(19) United States
(12) Patent Application Publication
(10) Pub. No.: US 2025/0081826 A1
(43) Pub. Date: Mar. 6, 2025

(54) DISPLAY SUBSTRATE, DISPLAY DEVICE AND MANUFACTURING METHOD THEREOF

(71) Applicants: YUNNAN INVENSIGHT OPTOELECTRONICS TECHNOLOGY CO., LTD., KUNMING, YUNNAN (CN); BOE TECHNOLOGY GROUP CO., LTD., Beijing (CN)

(72) Inventors: Yunhao ZHANG, Beijing (CN); Hongtao YU, Beijing (CN); Dongdong SU, Beijing (CN); Zongshun YANG, Beijing (CN); Kuanta HUANG, Beijing (CN); Weiliang BU, Beijing (CN); Yuhao LEE, Beijing (CN)

(21) Appl. No.: 18/580,483

(22) PCT Filed: Mar. 1, 2023
(86) PCT No.: PCT/CN2023/078963

§ 371 Date: Jan. 18, 2024

(51) Int. Cl. H10K 59/80; H10K 59/12; H10K 59/122; H10K 59/38

(52) U.S. Cl. CPC H10K 59/879; H10K 59/1201; H10K 59/122; H10K 59/38

(57) ABSTRACT

Embodiments of the present disclosure provide a display substrate, and a related display device and a manufacturing method. A display substrate includes a substrate, a first structural layer disposed on the substrate and including a plurality of protruding structures, and a lens layer disposed on the first structural layer and including a lens structure. An orthographic projection of the lens structure on the substrate overlaps with an orthographic projection of the protruding structure on the substrate.

### CROSS REFERENCE TO RELATED APPLICATIONS

This patent application is a National Stage Entry of PCT/CN2023/078963 filed on Mar. 1, 2023, the disclosure of which is incorporated by reference herein in its entirety as part of the present application.

### BACKGROUND

Embodiments of the present disclosure relate to the field of display technology, and particularly relate to a display substrate, a display device, and a manufacturing method thereof.

Organic Light-Emitting Diode (OLED) display panels have the advantages of self-illumination, high efficiency, bright colors, thinness and power saving, rollability, wide operating temperature range and so on, and have been gradually used in fields such as large-area display, lighting, and vehicle-mounted display and so on.

### BRIEF DESCRIPTION

Embodiments of the present disclosure provide a display substrate, and a related display device and a manufacturing method.

A first aspect of the present disclosure provides a display substrate. The display substrate includes a substrate, a first structural layer disposed on the substrate and including a plurality of protruding structures, and a lens layer disposed on the first structural layer and including a lens structure. An orthographic projection of the lens structure on the substrate overlaps with an orthographic projection of the protruding structure on the substrate.

In an embodiment of the present disclosure, a side of the first structural layer away from the substrate includes a plurality of grooves. The grooves are located between adjacent protruding structures. An orthographic projection of the groove on the substrate does not overlap with the orthographic projection of the lens structure on the substrate.

In an embodiment of the present disclosure, the display substrate further includes a second structural layer. The second structural layer is disposed between the first structural layer and the lens layer. A side of the second structural layer away from the substrate includes a plurality of notches. An orthographic projection of the notch on the substrate overlaps with the orthographic projection of the groove on the substrate.

In an embodiment of the present disclosure, a side of the first structural layer away from the substrate includes a plurality of protruding structures. The groove is located in a gap between adjacent protruding structures. An orthographic projection of at least one of the protruding structures on the substrate covers the orthographic projection of the lens structure on the substrate.

In an embodiment of the present disclosure, the orthographic projection of the groove on the substrate completely overlaps with the orthographic projection of the notch on the substrate.

In an embodiment of the present disclosure, the protruding structure is at least one of the following: a cylinder, an elliptical cylinder, and a polygonal cylinder.

In an embodiment of the present disclosure, in a direction perpendicular to a surface of the substrate, a height of the lens structure is greater than a depth of the notch, and greater than or equal to a depth of the groove.

In an embodiment of the present disclosure, in a direction parallel to a surface of the substrate, a size difference between an edge of at least one of the protruding structures and an edge of the lens structure on the protruding structure on the same side is less than or equal to the depth of the groove in a direction perpendicular to the substrate.

In an embodiment of the present disclosure, in a direction parallel to a surface of the substrate, a maximum size of the protruding structure is less than or equal to 3.5 μm.

In an embodiment of the present disclosure, in a direction parallel to a surface of the substrate, a minimum distance between two adjacent protruding structures is greater than or equal to 0.1 μm.

In an embodiment of the present disclosure, the display substrate further includes a filling portion filling the groove. The filling portion includes a light-shielding material. The light-shielding material has gas permeability.

In an embodiment of the present disclosure, material of the second structural layer includes metal oxide, such as Al₂O₃.

In an embodiment of the present disclosure, in the direction parallel to a surface of the substrate, a maximum size of the lens structure is between 3.0 μm and 3.6 μm, and in a direction perpendicular to the substrate, a height of the lens structure is less than or equal to 2.3 μm.

In an embodiment of the present disclosure, the first structural layer includes a plurality of structural layers. The plurality of structural layers may include at least one of an organic material layer or an inorganic material layer.

In an embodiment of the present disclosure, a side of the plurality of structural layers away from the substrate includes a planarization layer. The groove is located in the planarization layer. In a direction perpendicular to the substrate, the depth of the groove is less than a thickness of the planarization layer.

In an embodiment of the present disclosure, the display substrate further includes a light-emitting device layer located between the first structural layer and the substrate. The light-emitting device layer includes a plurality of light-emitting devices. The lens structures are arranged in one-to-one correspondence with the light-emitting devices.

In an embodiment of the present disclosure, the plurality of structural layers includes a color film layer. The color film layer includes a plurality of color films. The plurality of color films is arranged in one-to-one correspondence with the plurality of light-emitting devices.

In an embodiment of the present disclosure, the orthographic projection of the groove or the notch on the substrate partially overlaps with orthographic projections of at least two adjacent color films on the substrate.

In an embodiment of the present disclosure, the light-emitting device layer includes a first electrode layer and a pixel definition layer located on the substrate, a light-emitting layer located on the first electrode layer and the pixel definition layer, and a second electrode layer located on the light-emitting layer. The pixel definition layer defines a plurality of pixel openings. An orthographic projection of the pixel openings on the substrate does not overlap with the orthographic projection of the groove or the notch on the substrate.

A second aspect of the present disclosure provides a method for manufacturing a display substrate. The method includes providing a substrate, forming a first structural layer on the substrate, the first structural layer including a plurality of protruding structures, forming a lens layer on the first structural layer, and forming a lens structure in the lens layer. An orthographic projection of the lens structure on the substrate overlaps with an orthographic projection of the protruding structure on the substrate.

A third aspect of the present disclosure provides a display device. The display device includes the display substrate according to any embodiment in the first aspect.

Further aspects and scope of adaptability become apparent from the description provided herein. It should be understood that various aspects of the present application may be implemented alone or in combination with one or more other aspects. It should further be understood that the description and specific embodiments herein are intended for purposes of illustration only and are not intended to limit the scope of the present application.

### BRIEF DESCRIPTION OF THE DRAWINGS

The drawings described herein are for illustrative purposes only of selected embodiments and not all possible implementations, and are not intended to limit the scope of the present application, wherein:

FIG. 1 shows a cross-sectional view of a display substrate;

FIG. 2 shows a cross-sectional view of the display substrate according to an embodiment of the present disclosure;

FIG. 3 shows a top view of the display substrate in FIG. 2 according to an embodiment of the present disclosure;

FIG. 4 shows a scanned view of the display substrate in FIG. 2 according to an embodiment of the present disclosure;

FIG. 5 shows a flow chart of a method for manufacturing the display substrate according to an embodiment of the present disclosure;

FIG. 6 shows a cross-sectional view of the display substrate after step 520 according to an embodiment of the present disclosure;

FIG. 7 shows a cross-sectional view of the display substrate after step 530 according to an embodiment of the present disclosure;

FIG. 8 shows a cross-sectional view of the display substrate after step 540 according to an embodiment of the present disclosure;

FIG. 9 shows a cross-sectional view of the display substrate in which a transfer material layer has been formed according to an embodiment of the present disclosure;

FIG. 10 shows a cross-sectional view of the display substrate in which a transfer lens structure has been formed according to an embodiment of the present disclosure; and

FIG. 11 shows a schematic structural diagram of a display device according to an embodiment of the present disclosure.

Corresponding reference numbers indicate corresponding components or features throughout the various drawings. The drawings only show the positional relationship of various elements and are not drawn to scale.

### DETAILED DESCRIPTION

First, it should be noted that unless the context clearly dictates otherwise, the singular forms of words used herein and in the appended claims include the plural, and vice versa. Thus, when referring to the singular, the plural of the corresponding term is generally included. Similarly, the words “comprising” and “including” are to be interpreted as inclusively rather than exclusively. Likewise, the terms “including” and “or” should be construed to be inclusive unless otherwise indicated herein. Where the term “examples” is used herein, particularly when it follows a listing of terms is merely exemplary and illustrative, and should not be deemed to be exclusive or comprehensive.

In addition, it should also be noted that when introducing elements of the present application and embodiments thereof, the articles “a”, “an”, “the”, and “said” are intended to mean that there are one or more of the elements; unless otherwise stated, “a plurality of” means two or more; the terms “comprising”, “including”, “containing” and “having” are intended to be inclusive and mean that there may be additional elements other than the listed elements; the terms “first”, “second”, “third”, etc. are used for descriptive purposes only and should not be construed to indicate or imply relative importance and formation order.

Further, in the drawings, the thickness and areas of various layers are exaggerated for clarity. It should be understood that when a layer, region, or component is referred to as being “on” another part, it means that it is directly on the other part, or other components may also be between them. Conversely, when a component is referred to as being “directly” on another component, it means that no other components are between them. In embodiments of the present disclosure, “layer B is on layer A” means that layer B is located on a side of layer A in a direction away from the substrate.

Exemplary embodiments will now be described more fully with reference to the accompanying drawings.

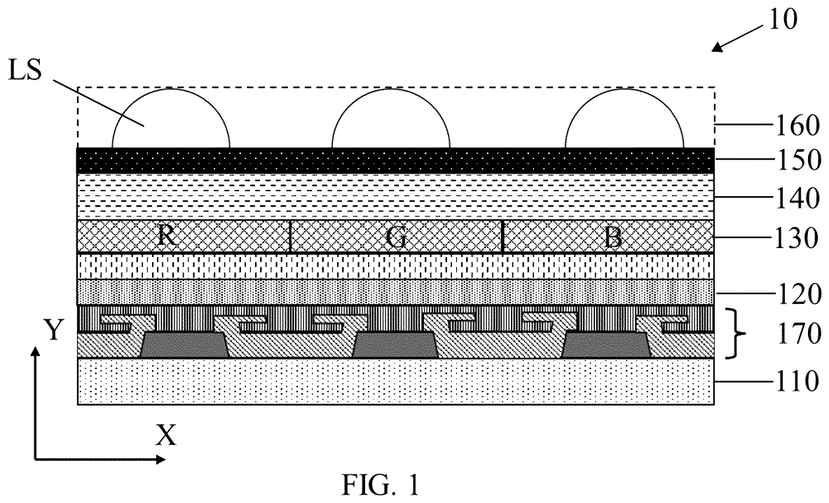

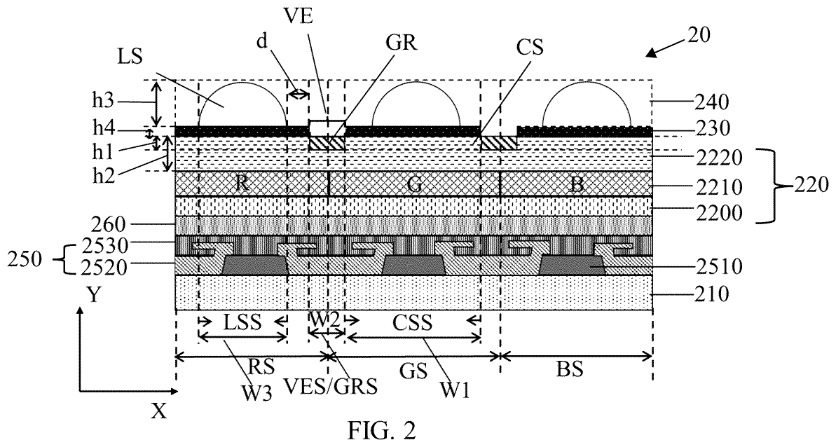

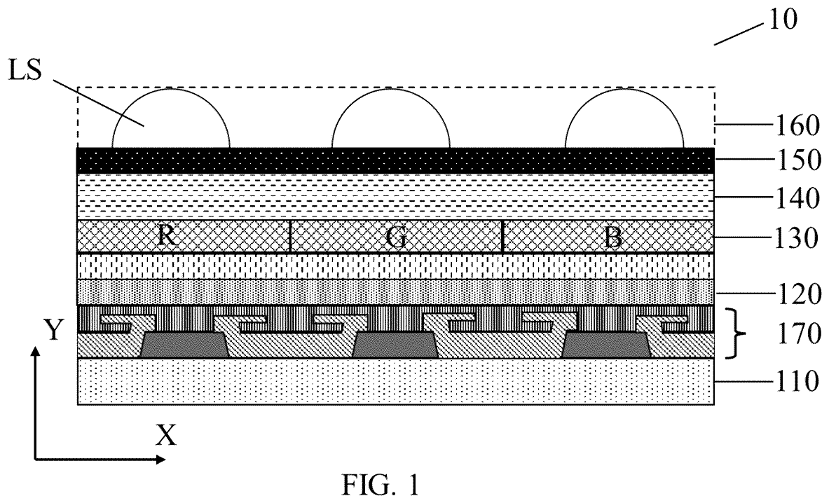

FIG. 1 shows a cross-sectional view of a display substrate. Generally, the display substrate 10, especially an organic light-emitting display substrate, includes a substrate 110, a light-emitting device layer 170, an adhesive layer 120 disposed on the light-emitting device layer 170, a color film layer 130 disposed on the adhesive layer 120, a planarization layer 140 disposed on the color film layer 130, and a lens layer 160 disposed on an etching barrier layer 150. Therein, the light-emitting device layer 170 includes a plurality of light-emitting devices. The lens layer 160 includes a plurality of lens structures LS. And the lens structures LS are arranged corresponding to the light-emitting devices. The adhesive layer 120 and the planarization layer 140 are made of inorganic materials or organic materials. For instance, the inorganic materials include silicon oxide, silicon nitride, silicon oxynitride, aluminum oxide, etc., and the organic materials include resin, but are not limited thereto. The color film layer 130 includes a plurality of color films. The plurality of color films may be at least one of the following: a red color film R, a green color film G, or a blue color film B. Each color film is arranged in one-to-one correspondence with each light-emitting device.

Additionally, the display substrate in FIG. 1 may further include an etching barrier layer 150 disposed between the planarization layer 140 and the lens layer 160. The etching barrier layer 150 is used to protect other layer structures from being etched during the manufacture process of the lens structure LS.

However, an inventor's research shows that the adhesive layer 120, the color film layer 130, and the planarization layer 140 may produce by-products such as water vapor or various gases (including acidic and alkaline gases). The by-products may cause undesirable physical and chemical effects on upper structural layers (i.e., lens layer 160 and/or etching barrier layer 150). Here, the physical effects include forces exerted on the upper structures due to gas expansion, causing it to deform or crack. The chemical effects include chemical interaction of acidic and/or alkaline gases with the upper structures, resulting in denaturation of the upper structure material (e.g., Al₂O₃). In addition, the physical and chemical effects will jointly cause changes in optical properties of the upper structure (such as refractive index and transmittance) or even cause the upper structure to fall off, so that the display device including the display substrate will have uneven brightness during using, leading to product defects, that is, the mura phenomenon.

The present disclosure provides the display substrate. In some embodiments of the display substrate, by forming a protruding structure on the planarization layer, gases generated by some structural layers between the lens layer and the substrate are discharged, thereby eliminating the mura of the display device including the display substrate and improving display quality.

Additionally, in some other embodiments of the display substrate, the display substrate includes the etching barrier layer, so that the gases generated by some structural layers between the etching barrier layer and the substrate are discharged through notches, thereby eliminating the mura of the display device including the display substrate and improving display quality.

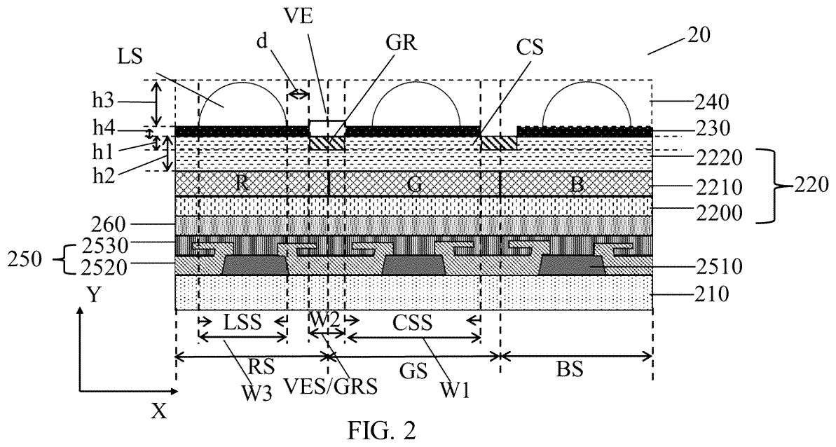

The display substrate will be described in detail below with reference to FIG. 2.

FIG. 2 shows a cross-sectional view of the display substrate according to an embodiment of the present disclosure. As shown in FIG. 2, the display substrate 20 includes a substrate 210, a first structural layer 220 disposed on the substrate 210, and a lens layer 240 disposed on the first structural layer 220, wherein the lens layer 240 includes the plurality of lens structures LS. In an embodiment of the present disclosure, the substrate 210 is similar to the substrate 110 in FIG. 1 and includes a flexible substrate or a glass substrate. The first structural layer 220 may include at least one of an organic material layer or an inorganic material layer. As shown in FIG. 2, the first structural layer 220 may include a color film layer 2210, a planarization layer 2220 disposed on a side of the color film layer 2210 away from the substrate 210, and an adhesive layer 2200 disposed on a side of the color film layer 2210 close to the substrate 210. In an embodiment of the present disclosure, the adhesive layer 2200, the color film layer 2210, and the planarization layer 2220 are respectively similar to the adhesive layer 120, the color film layer 130, and the planarization layer 140 in FIG. 1. In an embodiment of the present disclosure, the lens structure LS is similar to the lens structure LS in FIG. 1 and may be hemispherical.

The main difference between the display substrates shown in FIG. 2 and FIG. 1 is that the first structural layer 220 has a protruding structure CS, and there is a groove GR between adjacent protruding structures CS for discharging the gases (e.g., water vapor and other gases) generated by the first structural layer 220. The groove GR is located on a side of the first structural layer 220 away from the substrate 210. The protruding structure CS is on a surface of the first structural layer 220 away from the substrate 210, and an orthographic projection CES of the protruding structure CE on the substrate 210 overlaps with an orthographic projection LSS of the lens structure LS on the substrate 210, for instance, in the center. That is, the orthographic projection CSS of at least one of the protruding structures CS on the substrate covers the orthographic projection LSS of the lens structure LS on the substrate 210. An orthographic projection GRS of the groove GR on the substrate 210 does not overlap with the orthographic projection LSS of the lens structure LS on the substrate 210. Exemplarily, as shown in FIG. 2, a plurality of grooves GR are located in the planarization layer 2220, and along a direction Y perpendicular to the substrate 210, depth h1 of the groove GR is less than thickness h2 of the planarization layer 2220. The orthographic projection GRS overlaps with orthographic projections of at least two adjacent color film portions on the substrate 210. In an embodiment of the present disclosure, the orthographic projection GRS overlaps with the orthographic projections of two adjacent color film portions on the substrate 210, and the orthographic projections of the two color film portions on the substrate include RS and GS, GS and BS, or RS and BS (not shown). Exemplarily, the protruding structure CS may be cylindrical. In other embodiments of the present disclosure, the protruding structure CS may also have other shapes, such as an elliptical cylinder or a polygonal cylinder, but is not limited thereto. In an embodiment of the present disclosure, in a direction parallel to the surface of the substrate 210, the maximum size W1 of the protruding structure CS is greater than or equal to the maximum size W2 of the groove GR. Exemplarily, the maximum size W1 of the protruding structure CS is less than or equal to 3.5 μm, and the minimum value of the size of the groove GR between adjacent protruding structures CS is greater than or equal to 0.1 μm, so that the gas released from the first structural layer 220 can be smoothly discharged from the groove GR, while ensuring structural stability.

Additionally, in other embodiments of the present disclosure, the display substrate 20 further includes a second structural layer 230. The second structural layer 230 is disposed between the first structural layer 220 and the lens layer 240. The main difference between this display substrate and the display substrate shown in FIG. 1 is that there is a notch VE in the second structural layer 230 for discharging the gas generated by the first structural layer 220 together with the groove GR. In an embodiment of the present disclosure, a material forming the second structural layer 230 includes a material with low or non-gas permeability, such as a metal oxide, specifically Al₂O₃. The second structural layer 230 is similar to the etching barrier layer 150 in FIG. 1 and protects other layer structures when forming the lens structure LS. And the etching barrier layer 150 includes a single-layer structure or a multi-layer structure. For instance, the etching barrier layer 150 has a double-layer structure, which is not limited here and can be set according to actual requirements. An orthographic projection VES of the notch VE on the substrate 210 does not overlap with the orthographic projection LSS of the lens structure LS on the substrate 210. The notch VE and the groove GR are arranged correspondingly. That is, there is an overlapping area between the orthographic projection VES of the notch VE on the substrate 210 and the orthographic projection GRS of the groove GR on the substrate 210. And there are situations where the orthographic projection GRS of the groove GR on the substrate 210 partially overlaps or completely overlaps with the orthographic projection VES of the notch VE on the substrate 210. Similar to the groove GR, the notch VE is also located between adjacent lens structures LS. That is, the orthographic projection VES of the notch VE on the substrate 210 does not overlap with the orthographic projection LSS of the lens structure LS on the substrate 210. The orthographic projection VES overlaps with the orthographic projections of at least two adjacent color film portions on the substrate 210.

In an embodiment of the present disclosure, the display substrate 20 further includes a filling portion filling the groove GR (in FIG. 2, the filling portion and the notch VE occupy approximately same space). In an embodiment of the present disclosure, the filling portion includes a light-shielding material that has gas permeability. Exemplarily, the light-shielding material may include a black matrix.

In some embodiments of the present disclosure, in the direction X parallel to the surface of the substrate 210, the maximum size W3 of the lens structure LS is greater than height h3 of the lens structure LS. Exemplarily, in the direction X along the surface of the substrate 210, the maximum size W3 of the lens structure LS is between 3.0 μm and 3.6 μm, such as 3.2 μm and 3.4 μm. In the direction Y perpendicular to the surface of the substrate 210, the height h3 of the lens structure LS is less than or equal to 2.3 μm, for instance, between 2.0 μm and 2.2 μm.

In some embodiments of the present disclosure, the maximum size W3 of the lens structure LS in the direction X parallel to the surface of the substrate 210 is greater than thickness h4 of the second structural layer 230 in the direction Y perpendicular to the substrate 210. Exemplarily, the thickness h4 of the second structural layer 230 in the direction Y perpendicular to the substrate 210 is 4 nm-5 nm. The second structural layer 230 with this thickness may form the notch VE while ensuring the size of the lens structure LS, so that the gas generated by the first structural layer 220 may be discharged from the notch VE.

In some embodiments of the present disclosure, in the direction Y perpendicular to the substrate 210, the depth h1 of the groove GR is greater than the depth h4 of the notch VE. For instance, in the direction Y perpendicular to the surface of the substrate 210, the depth h1 of the groove GR in the planarization layer 2220 is greater than or equal to 310 nm, and the depth h4 of the notch VE is 4 nm-5 nm.

In some embodiments of the present disclosure, in the direction X parallel to the surface of substrate 210, the size difference d between an edge of at least one of the protruding structures CS and an edge of the lens structure LS on the protruding structure on the same side is less than or equal to the depth h1 of the groove GR in the direction Y perpendicular to the substrate 210. In this way, while ensuring the size of the lens structure LS, the depth h1 of the groove GR is increased so that the gas generated by the first structural layer 220 may be better discharged.

In some embodiments of the present disclosure, in the direction Y perpendicular to the surface of the substrate 210, the height h3 of the lens structure LS is greater than the depth h4 of the notch VE and greater than or equal to the depth h1 of the groove GR.

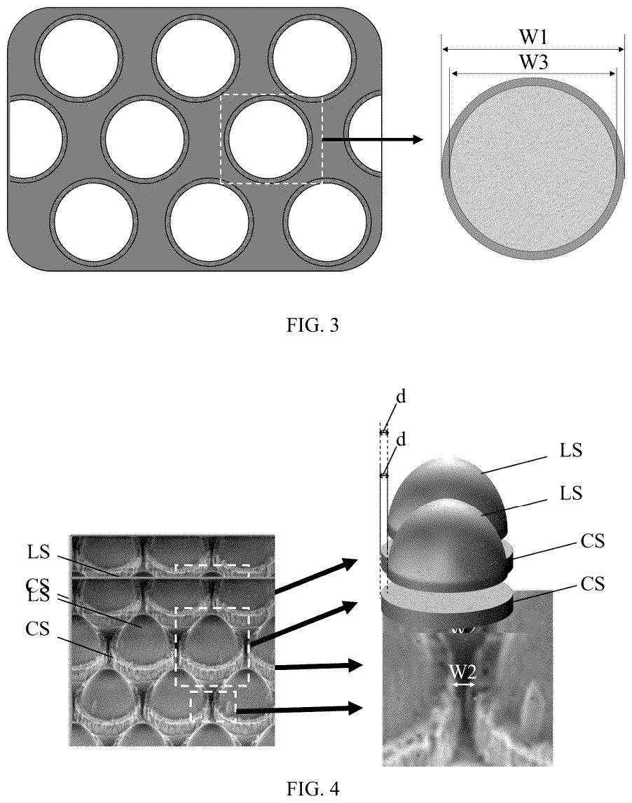

The groove GR, the protruding structure CS and the lens structure LS will be described in detail below with reference to FIGS. 3 and 4.

FIG. 3 shows a top view of the display substrate in FIG. 2 according to an embodiment of the present disclosure. In an embodiment of the present disclosure, the lens structure LS is a hemisphere and the convex structure CS is a cylinder. As shown in FIG. 3, a center of the lens structure LS is aligned with a center of the protruding structure CS. In the direction X parallel to the surface of the substrate 210, the maximum size W3 of the lens structure LS is smaller than the maximum size W1 of the protruding structure CS. Exemplarily, the maximum size W3 of the lens structure LS is 3.2 μm, and the maximum size W1 of the protruding structure CS is 3.5 μm.

FIG. 4 shows a scanned view of the display substrate in FIG. 2 according to an embodiment of the present disclosure. In an embodiment of the present disclosure, in the direction X parallel to the surface of the substrate 210, the size W2 of the groove GR between adjacent protruding structures CS is greater than the size difference d between the edge of at least one of the protruding structures CS and the edge of the lens structure LS on this protruding structure on the same side. As shown in FIG. 4, the groove GR in the planarization layer 2220 defines a cylindrical protruding structure CS. In an embodiment of the present disclosure, the groove GR is irregularly shaped. In the direction X parallel to the surface of the substrate 210, the distance between two adjacent protruding structures CS (i.e., the size W2 of the groove GR) is at least 0.1 μm to ensure that gas can be smoothly discharged through the notch.

In some embodiments of the present disclosure, the first structural layer 220 may only include the color film layer 2210.

In some other embodiments of the present disclosure, the first structural layer 220 includes at least one of the following: the color film layer 2210, the planarization layer 2220, or the adhesive layer 2200.

In other embodiments of the disclosure, the orthographic projection GRS of the groove GR on the substrate 210 at least partially overlaps with the orthographic projection VES of the notch VE on the substrate 210. There are the situations where the orthographic projection GRS of the groove GR on the substrate 210 completely overlaps with the orthographic projection VES of the notch VE on the substrate 210.

Additionally, as shown in FIG. 2, in addition to the structures as mentioned above, the display substrate 20 further includes other structural layers between the first structural layer 220 and the substrate 210. For instance, these structural layers may include a light-emitting device layer 250 disposed on the substrate 210, and an encapsulation layer 260 disposed on the light-emitting device layer 250. In an embodiment of the present disclosure, the light-emitting device layer 250 includes a first electrode layer 2510 (e.g., an anode layer) and a pixel definition layer 2520 located on the substrate 210, a light-emitting layer 2530 located on the first electrode layer 2510 and the pixel definition layer 2520, and a second electrode layer (e.g., a cathode layer, not shown) located on the light-emitting layer 2530. In an embodiment of the present disclosure, a partition structure is disposed in the pixel definition layer 2520 to prevent crosstalk between lights from different light-emitting elements.

The present disclosure further provides a method for manufacturing the display substrate. The manufacturing method will be described in detail below with reference to the accompanying drawings.

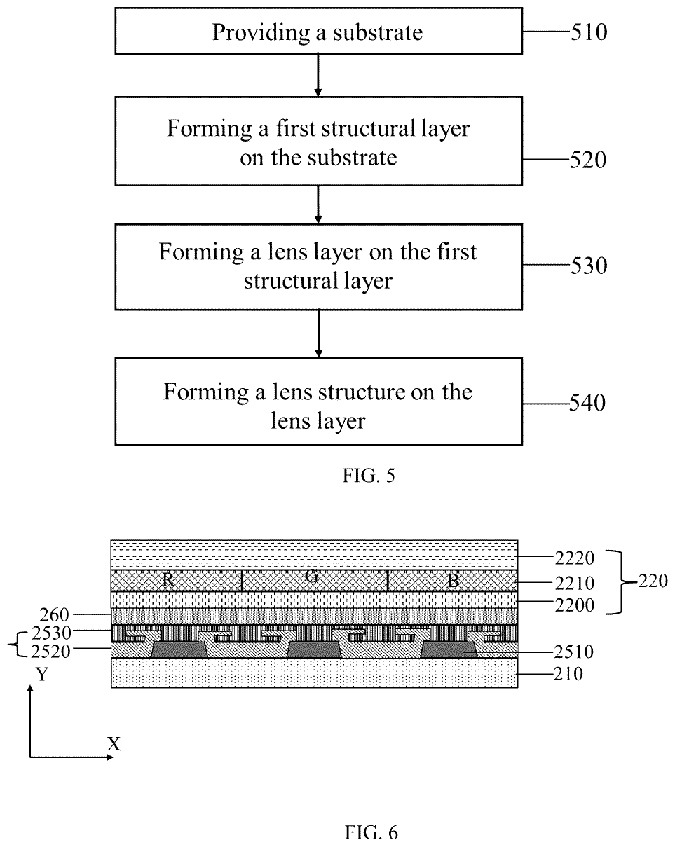

FIG. 5 shows a flow chart of the method for manufacturing the display substrate according to an embodiment of the present disclosure.

The method includes providing a substrate at step 510. In an exemplary embodiment of the present disclosure, the substrate 210 may include the flexible substrate, for instance, a flexible material such as polyimide, but is not limited thereto. Alternatively, the substrate 210 may also include the glass substrate.

Exemplarily, the method for manufacturing the display substrate in the present application may further include forming the light-emitting device layer 250 on a side of the substrate 210, and forming the encapsulation layer 260 on the side of the light-emitting device layer 250 away from the substrate. Forming the light-emitting device layer 250 on the side of the substrate 210 includes forming the first electrode layer 2510 and the pixel definition layer 2520 on the substrate, and the first electrode layer 2510 may be an anode layer, forming the light-emitting layer 2530 on the first electrode layer 2510 and the pixel definition layer 2520, and the material forming the light-emitting layer 2530 may be the organic light-emitting material, and forming the second electrode layer on the light-emitting layer 2530. In an embodiment of the present disclosure, as described above with reference to FIG. 2, the partition structure is disposed in the pixel definition layer 2520 to prevent crosstalk between lights from different light-emitting elements.

The method includes forming the first structural layer on the substrate at step 520. The first structural layer includes a plurality of protruding structures. As described above, the first structural layer 220 may include at least one of the organic material layer and the inorganic material layer. FIG. 6 shows a cross-sectional view of the display substrate after step 520 according to an embodiment of the present disclosure. As shown in FIG. 6, the first structural layer 220 may include the adhesive layer 2200, the color film layer 2210, and the planarization layer 2220. Forming the first structural layer 220 on the substrate 210 may include forming the adhesive layer 2200 on the substrate 210, forming the color film layer 2210 on the adhesive layer 2200, forming the planarization layer 2220 on the color film layer 2210, and forming the protruding structure CS on the planarization layer 2220. The protruding structure CS may be cylindrical. In other embodiments of the present disclosure, the protruding structure CS may further have other shapes, such as an elliptical cylinder or a polygonal cylinder, but is not limited thereto. In an embodiment of the present disclosure, as described above, in the direction X parallel to the surface of the substrate 210, the maximum size W1 of the protruding structure CS is greater than or equal to the maximum size W2 of the groove GR. Exemplarily, the maximum size W1 of the protruding structure CS is less than or equal to 3.5 μm, and the minimum value of the size of the groove GR between adjacent protruding structures CS is greater than or equal to 0.1 μm. This configuration can allow the gas released from the first structural layer 220 to be smoothly discharged from between the protruding structures CS while ensuring the stability of the structure.

Additionally, the method for manufacturing the display substrate shown in FIG. 5 further includes forming the groove in the planarization layer 2220. In an embodiment of the present disclosure, in the direction Y perpendicular to the substrate 210, the depth h1 of the groove GR is smaller than the thickness h2 of the planarization layer 2220. As described above, exemplarily, the depth h1 of the groove GR may be at least 310 nm. In an embodiment of the present disclosure, the orthographic projection GRS overlaps with the orthographic projection LSS, for instance, in the center. The orthographic projection GRS overlaps with the orthographic projections of two adjacent color film portions on the substrate 210. The orthographic projections of the two color film portions on the substrate include RS and GS, GS and BS, or RS and BS (not shown). The specific process of forming the groove GR will be described together with the process of forming the lens structure LS below.

In another embodiment of the present disclosure, the organic material layer may only include the adhesive layer 2200 and the color film layer 2210. Forming the first structural layer 220 on the substrate 210 may include forming the adhesive layer 2200 on the substrate 210, and forming the color film layer 2210 on the adhesive layer 2200. In yet another embodiment of the present disclosure, the organic material layer may only include the color film layer 2210 and the planarization layer 2220. Forming the first structural layer 220 on the substrate 210 may include forming the color film layer 2210 on the substrate 210, and forming the planarization layer 2220 on the color film layer 2210.

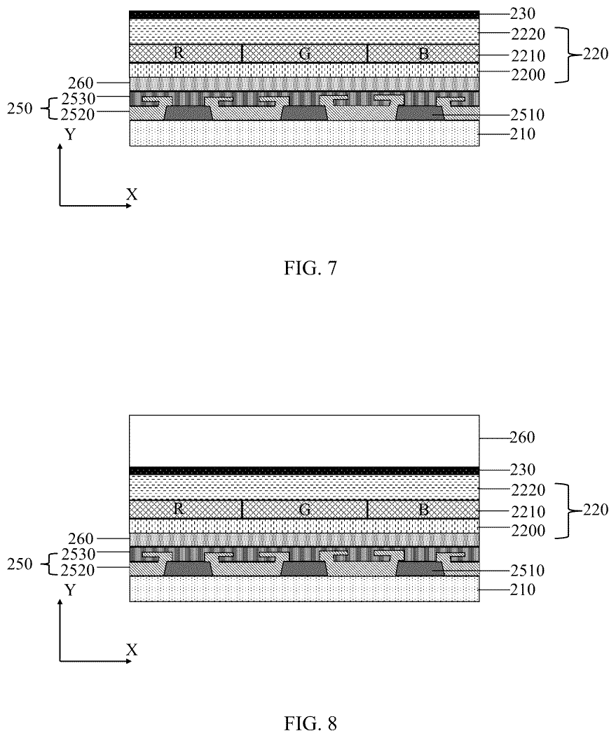

Additionally, the method for manufacturing the display substrate shown in FIG. 5 may further include forming the second structural layer on the first structural layer. As mentioned above, the material forming the second structural layer 230 includes the material with low gas permeability or non-gas permeability, such as the metal oxide, specifically Al₂O₃. Forming the second structural layer 230 on the first structural layer 220 includes forming the second structural layer 230 on the first structural layer 220, and forming the notch VE in the second structural layer 230. In an embodiment of the present disclosure, the notch VE and the groove GR are arranged in one-to-one correspondence. As mentioned above, the second structural layer 230 protects the other layer structures when forming the lens structure LS. The second structure layer 230 includes the single-layer structure or the multi-layer structure, which is not limited here and can be set according to actual requirements. Exemplarily, the thickness h4 of the second structural layer 230 is 4 nm to 5 nm. The second structural layer 230 with this thickness may form the notch VE and the groove GR while ensuring the size of the lens structure LS. FIG. 7 shows a cross-sectional view of the display substrate after forming the second structural layer according to an embodiment of the present disclosure. As shown in FIG. 7, no notches VE is formed in the second structural layer 230. The specific process of forming the notch VE will be described together with the process of forming the lens structure LS below. In this embodiment, the formed notch VE satisfies the following conditions: there is an overlapping area between the orthographic projection VES of the notch VE on the substrate 210 and the orthographic projection GRS of the groove GR on the substrate 210, and there are the situations where the orthographic projection GRS partially overlaps or completely overlaps with the orthographic projection VES.

The method includes forming the lens layer on the first structural layer at step 530. The material of lens layer 240 include silicon nitride. In an embodiment of the present disclosure, the thickness of the lens layer 240 is 2.2 μm to 2.3 μm.

Alternatively, in another embodiment of the present disclosure, the display substrate includes the second structural layer. Manufacturing step 530 may be replaced by forming the lens layer on the second structural layer. FIG. 8 shows a cross-sectional view of the display substrate after step 540 according to an embodiment of the present disclosure.

The method includes forming a lens structure in the lens layer at step 540. Forming the lens structure LS in the lens layer 240 includes forming a transfer material layer 270 on the lens layer 240, forming a transfer lens structure TLS in the transfer material layer 270, and transferring the transfer lens structure TLS to the lens layer 240 to form the lens structure LS.

In an embodiment of the present disclosure, as mentioned above, the maximum size W3 of the lens structure LS is larger than the thickness h4 of the second structural layer 230 in the X direction. The maximum size W3 of the lens structure LS is smaller than the maximum size W1 of the protruding structure CS. The size difference d between the edge of at least one of the protruding structures CS and the edge of the lens structure LS on the protruding structure on the same side is less than or equal to the depth h1 of the groove GR in the direction Y perpendicular to the substrate 210. Exemplarily, the maximum size W3 of the lens structure LS is 3.2 μm, and the maximum size W1 of the protruding structure CS is 3.5 μm. In this way, while ensuring the size of the lens structure LS, the depth h1 of the groove GR is increased so that the gas generated by the first structural layer 220 can be better discharged.

In the Y direction, the height h3 of the lens structure LS is greater than the depth h4 of the notch VE and greater than or equal to the depth h1 of the groove GR. Exemplarily, the height h3 of the lens structure LS is less than or equal to 2.3 μm, for example, between 2 μm and 2.2 μm.

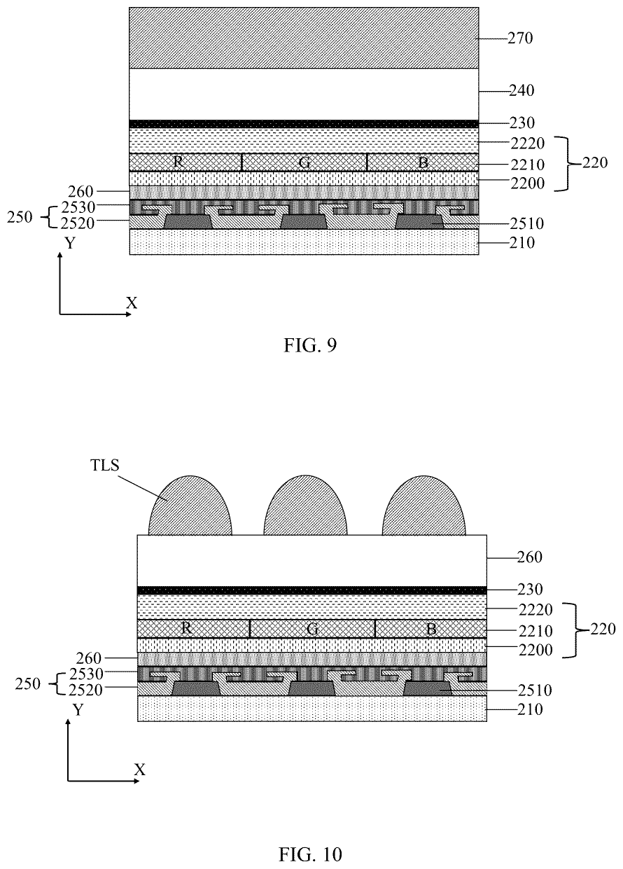

FIG. 9 shows a cross-sectional view of the display substrate on which the transfer material layer has been formed according to an embodiment of the present disclosure. In an embodiment of the present disclosure, the material forming the transfer material layer 270 includes the material TOK TMP 15 from the TOK Company or other similar materials.

In an embodiment of the present disclosure, for example, forming the transfer lens structure TLS in the transfer material layer 270 includes exposing the transfer material layer 270 using ultraviolet light with a wavelength of 365 nm and a power of 150 mJ, developing and additionally or optionally cleaning the exposed transfer material layer 270 using a developer to obtain the material layer with a cylindrical structure, and heating the cylindrical structure to form the hemispherical transfer lens structure TLS.

FIG. 10 shows a cross-sectional view of the display substrate on which the transfer lens structure has been formed according to an embodiment of the present disclosure. In an embodiment of the present disclosure, in the X direction, the maximum size of the transfer lens structure TLS is between 3.5 μm and 3.6 μm. And in the Y direction, the height of the transfer lens structure TLS is between 1.38 μm and 1.41 μm.

In an embodiment of the present disclosure, for example, transferring the transfer lens structure TLS to the lens layer 240 to form the lens structure LS includes selectively etching the display substrate having the transfer lens structure TLS using a first high-energy plasma bombardment (ESL) and a second ESL, to form the lens structure LS in the lens layer 240 and the groove GR in the planarization layer 2230. Specifically, a first gas used for the first ESL includes phosphorus hexafluoride (main reactivity gas) such as PF6 and argon (auxiliary gas). The first ESL mainly etches the lens layer 240 (silicon nitride), but has a low etching rate for the second structural layer 230 (Al₂O₃). By means of the first ESL, the lens layer 240 can have a surface morphology with lenses. The surface morphology may include multiple non-overlapping partial spheres, or partial overlapping partial spheres. The second gas used for the second ESL includes chlorine (the main reactivity gas), and helium and titanium tetrafluoride (the auxiliary gases). The second ESL mainly etches the second structural layer 230 (Al₂O₃) (silicon nitride), but has the low etching rate for the lens layer 240. By means of the second ESL, the lens layer 240 with the surface morphology of lenses can form the lens structure LS, the notch VS can be formed in the second structural layer 230, and the groove GR can be formed in the planarization layer 2230, as shown in FIG. 2. As mentioned above, in the formed display substrate 20, the orthographic projection GRS of the groove GR on the substrate 210 does not overlap with the orthographic projection LSS of the lens structure LS on the substrate 210, but partially overlaps, or completely overlaps, with the orthographic projection VES of the notch VE on the substrate 210.

In yet another embodiment of the present disclosure, in the formed display substrate, the orthographic projection GRS of the groove GR on the substrate 210 does not overlap with the orthographic projection LSS of the lens structure LS on the substrate 210, but partially overlaps with the orthographic projection VES of the notch VE on the substrate 210.

Additionally, the method for manufacturing the display substrate 200 further includes depositing a material with the gas permeability in the groove GR. In an embodiment of the present disclosure, the material includes the light-shielding material, such as the black matrix. In the direction Y perpendicular to the surface of the substrate 210, the thickness of the black matrix in the filling portion may be at least 310 nm to achieve light shielding and color crosstalk prevention. In other implementations of the disclosure, the material is a transparent breathable material. In this embodiment, the thickness of the black matrix in the filling portion is no longer limited to 310 nm or more.

An embodiment of the present disclosure further provides a display device, which includes the display panel according to any embodiment of the present disclosure.

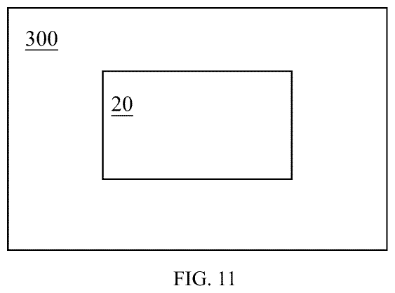

FIG. 11 shows a schematic structural diagram of the display device according to an embodiment of the present disclosure. As shown in FIG. 11, the display device 300 may include the display substrate 20 according to any embodiment of the present disclosure.

The display device 300 may be a mobile phone, a tablet computer, a television, a monitor, a laptop computer, a digital photo frame, a navigator, or any other product or component with a display function.

The display panel and display device provided by the embodiments of the present disclosure have the same or similar beneficial effects as the array substrate provided by the previous embodiments of the present disclosure. Because the array substrate has been described in detail in the foregoing embodiments, the beneficial effects will not be described again here.

The foregoing description of the embodiments has been provided for the purposes of illustration and description, and is not intended to be exhaustive or to limit the present application. The respective elements or features of a particular embodiment are generally not limited to that particular embodiment, but when appropriate, these elements and features are interchangeable and can be used in a selected embodiment even if not specifically shown or described. Likewise, they can be changed in many ways. Such changes are not to be considered as a departure from the present application and all such modifications are included within the scope of the present application.

1. A display substrate comprising:
a substrate;
a first structural layer disposed on the substrate and comprising a plurality of protruding structures; and
a lens layer disposed on the first structural layer and comprising a plurality of lens structures;
wherein an orthographic projection of the lens structure on the substrate overlaps with an orthographic projection of the protruding structure on the substrate.

2. The display substrate according to claim 1, wherein a side of the first structural layer away from the substrate comprises a plurality of grooves located between adjacent protruding structures, and wherein an orthographic projection of the groove on the substrate does not overlap with the orthographic projection of the lens structure on the substrate.

3. The display substrate according to claim 2, further comprising a second structural layer disposed between the first structural layer and the lens layer, wherein a side of the second structural layer away from the substrate comprises a plurality of notches, and wherein an orthographic projection of the notch on the substrate overlaps with the orthographic projection of the groove on the substrate.

4. The display substrate according to claim 3, wherein the orthographic projection of the groove on the substrate completely overlaps with the orthographic projection of the notch on the substrate.

5. The display substrate according to claim 3, wherein the protruding structure comprises at least one of a cylinder, an elliptical cylinder, and a polygonal cylinder.

6. The display substrate according to claim 3, wherein in a direction perpendicular to a surface of the substrate, a height of the lens structure is greater than a depth of the notch, and greater than or equal to a depth of the groove.

7. The display substrate according to claim 3, wherein in a direction parallel to a surface of the substrate, a size difference between an edge of at least one of the protruding structures and an edge of the lens structure on the protruding structure on the same side is less than or equal to the depth of the groove in a direction perpendicular to of the substrate.

8. The display substrate according to claim 3, wherein in a direction parallel to a surface of the substrate, a maximum size of the protruding structure is less than or equal to 3.5 μm.

9. The display substrate according to claim 3, wherein in a direction parallel to a surface of the substrate, a minimum distance between two adjacent protruding structures is greater than or equal to 0.1 μm.

10. The display substrate according to claim 3, further comprising a filling portion filling the groove, wherein the filling portion comprises light-shielding material, and wherein the light-shielding material has gas permeability.

11. The display substrate according to claim 3, wherein the second structural layer comprises Al₂O₃.

12. The display substrate according to claim 1, wherein in a direction parallel to a surface of the substrate, a maximum size of the lens structure is between 3.0 μm and 3.6 μm, and wherein in a direction perpendicular to the surface of the substrate, a height of the lens structure is less than or equal to 2.3 μm.

13. The display substrate according to claim 3, wherein the first structural layer comprises a plurality of structural layers, and wherein the plurality of structural layers comprise at least one of an organic material layer or an inorganic material layer.

14. The display substrate according to claim 13, wherein the plurality of structural layers comprises a planarization layer on a side thereof away from the substrate, wherein the groove is located in the planarization layer, wherein in a direction perpendicular to a surface of the substrate, and wherein the depth of the groove is less than a thickness of the planarization layer.

15. The display substrate according to claim 14, further comprising a light-emitting device layer located between the first structural layer and the substrate, wherein the light-emitting device layer comprises a plurality of light-emitting devices, and wherein the lens structures are arranged in one-to-one correspondence with the light-emitting devices.

16. The display substrate according to claim 15, wherein the plurality of structural layers comprises a color film layer comprising a plurality of color films, and wherein the plurality of color films is arranged in one-to-one correspondence with the plurality of light-emitting devices.

17. The display substrate according to claim 16, wherein the orthographic projection of the groove or the notch on the substrate partially overlaps with orthographic projections of at least two adjacent color films on the substrate.

18. The display substrate according to claim 15, wherein the light-emitting device layer comprises:
a first electrode layer and a pixel definition layer located on the substrate;
a light-emitting layer located on the first electrode layer and the pixel definition layer; and
a second electrode layer located on the light-emitting layer;
wherein the pixel definition layer defines a plurality of pixel openings, and wherein an orthographic projection of the pixel openings on the substrate does not overlap with the orthographic projection of the groove or the notch on the substrate.

19. A method for manufacturing a display substrate, the method comprising:
providing a substrate;
forming a first structural layer on the substrate which comprises a plurality of protruding structures;
forming a lens layer on the first structural layer; and
forming lens structures in the lens layer;
wherein an orthographic projection of the lens structure on the substrate overlaps with an orthographic projection of the protruding structure on the substrate.

20. A display device comprising the display substrate according to claim 1.
